(19) United States
(12) Patent Application Publication
(10) Pub. No.: US 2010/0165229 A1
(43) Pub. Date: Jul. 1, 2010

(54) FASTENING STRUCTURE FOR DISPLAY PANEL AND HANDHELD ELECTRONIC DEVICE HAVING THE SAME

(75) Inventors: Ding Lu, Shanghai City (CN); Shen Zhang, Shanghai City (CN); Martin Hsu, Taipei (TW)

Correspondence Address: J C PATENTS, 4 VENTURE, SUITE 250, IRVINE, CA, 92618, US

(73) Assignee: Inventec Appliances Corp., Taipei (TW)

(21) Appl. No.: 12/411,204

(22) Filed: Mar. 25, 2009

(30) Foreign Application Priority Data
Dec. 29, 2008 (TW) 97223559

(51) Int. Cl. G02F 1/1333; H05K 5/00

(52) U.S. Cl. 349/58; 361/679.01; 361/679.3

(57) ABSTRACT

A fastening structure of a display panel includes a base plate, first sidewalls, a frame connected to the base plate and surrounded by the first sidewalls, and stiffeners. The first sidewalls are connected together and connected to the base plate. The frame accommodates the display panel. The stiffeners having a trapezoid-shaped structure or a triangle-shaped structure connect the base plate to the frame. The stiffeners are located between the frame and the first sidewalls. A gap respectively exists between the stiffeners and the first sidewalls. Therefore, the stiffeners enhance the strength between the base plate and the frame accommodating the display panel. Due to the gap respectively existing between the stiffeners and the first sidewalls, when the fastening structure is impacted, a force transmitted to the frame is reduced by the gap to effectively protect the display panel.

### CROSS-REFERENCE TO RELATED APPLICATION

This application claims the priority benefit of Taiwan application serial no. 97223559, filed on Dec. 29, 2008. The entirety of the above-mentioned patent application is hereby incorporated by reference herein and made a part of specification.

### BACKGROUND OF THE INVENTION

1. Field of Invention

The present invention relates to a fastening structure and a handheld electronic device having the same. More particularly, the present invention relates to a fastening structure for a display panel and a handheld electronic device having the same.

2. Description of Related Art

With advancement of information technology at present, it becomes easier and easier to obtain necessary information from daily-used electronic devices. Besides, the progress of technology results in development of light, thin, short, and compact electronic devices. Based on the above advantages, handheld electronic devices are well accepted by the public and extensively applied in our daily lives.

In addition to facilitation of information processing in an efficient manner, the handheld electronic device featuring reliability has also become one of the major choices of consumers. Hence, the structural strength of the handheld electronic device should be enhanced, so as to better prevent the handheld electronic device from being damaged due to collision. For instance, the contact between a side surface of a fluorescent tube in a handheld electronic device and a fastening structure for fastening a display panel is rigid, and therefore when the handheld electronic device is impacted by an external force, the impact is communicated from a case of the handheld electronic device to the fastening structure. As such, sides of the display panel in the handheld electronic device are impacted, thus giving rise to damage to or dysfunction of the display panel.

### SUMMARY OF THE INVENTION

The present invention is directed to a fastening structure for a display panel and a handheld electronic device having the same, so as to prevent the display panel from being directly affected by an external force.

In the present invention, a fastening structure for a display panel including a base plate, a plurality of first sidewalls, a frame, and a plurality of stiffeners is provided. The first sidewalls are connected together and respectively connected to the base plate. The frame is connected to the base plate and surrounded by the first sidewalls. The frame is used to accommodate the display panel. The stiffeners are connected to the base plate and the frame. Besides, the stiffeners are located between the frame and the first sidewalls, and a gap respectively exists between each of the stiffeners and each of the first sidewalls.

According to an embodiment of the present invention, the base plate has a display opening for corresponding to the display panel. When the display panel is disposed in the frame, the display opening exposes a display region of the display panel.

According to an embodiment of the present invention, the frame has a plurality of second sidewalls and a supporting portion. The second sidewalls are connected together and connected to the base plate. The supporting portion is connected to the second sidewalls and extending from the second sidewalls towards inside of the frame. When the display panel is disposed in the frame, the supporting portion is used to support the display panel.

According to an embodiment of the present invention, a height of the second sidewalls relative to the base plate is substantially less than a height of the first sidewalls relative to the base plate.

According to an embodiment of the present invention, the stiffeners are connected to two of the second sidewalls opposite to each other.

According to an embodiment of the present invention, at least parts of the stiffeners are respectively located to junctions of the second sidewalls.

According to an embodiment of the present invention, the stiffeners respectively have a trapezoid-shaped structure or a triangle-shaped structure.

According to an embodiment of the present invention, the base plate, the frame, the stiffeners, and the first sidewalls are integrally formed.

In the present invention, a handheld electronic device including a display panel, a processing unit, and a fastening structure is provided. The processing unit is connected to the display panel for outputting a display signal to the display panel. The fastening structure includes a base plate, a plurality of first sidewalls, a frame, and a plurality of stiffeners. The first sidewalls are connected together and respectively connected to the base plate. The frame is connected to the base plate and surrounded by the first sidewalls. The frame is used to accommodate the display panel. The stiffeners are connected to the base plate and the frame. Besides, the stiffeners are located between the frame and the first sidewalls, and a gap respectively exists between each of the stiffeners and each of the first sidewalls.

According to an embodiment of the present invention, the base plate has a display opening for corresponding to the display panel. When the display panel is disposed in the frame, the display opening exposes a display region of the display panel.

According to an embodiment of the present invention, the frame has a plurality of second sidewalls and a supporting portion. The second sidewalls are connected together and connected to the base plate. The supporting portion is connected to the second sidewalls and extending from the second sidewalls towards inside of the frame. When the display panel is disposed in the frame, the supporting portion is used to support the display panel.

According to an embodiment of the present invention, a height of the second sidewalls relative to the base plate is substantially less than a height of the first sidewalls relative to the base plate.

According to an embodiment of the present invention, the stiffeners are connected to two of the second sidewalls opposite to each other.

According to an embodiment of the present invention, parts of the stiffeners are respectively connected to junctions of the second sidewalls.

According to an embodiment of the present invention, the stiffeners respectively have a trapezoid-shaped structure or a triangle-shaped structure.

According to an embodiment of the present invention, the base plate, the frame, the stiffeners, and the first sidewalls are integrally formed.

According to an embodiment of the present invention, the display panel is a liquid crystal display (LCD) panel or an organic light emitting diode (OLED) display panel.

In light of the foregoing, the stiffeners are capable of enhancing strength between the base plate and the frame. Moreover, a gap respectively exists between each of the stiffeners and each of the first sidewalls in the fastening structure of the present invention. Thereby, when the handheld electronic device is impacted by a force, the force is not transmitted to the frame through the stiffeners, and the display panel is not damaged accordingly. As such, the display panel of the handheld electronic device can be protected in an effective manner.

In order to make the aforementioned and other features and advantages of the present invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A is a schematic view of a handheld electronic device according to an embodiment of the present invention.

FIG. 1B is a cross-sectional view of the handheld electronic device depicted in FIG. 1A taken along a line A-A′.

FIG. 1C is a schematic exploded view of the handheld electronic device depicted in FIG. 1A.

FIG. 2A is a schematic view of a handheld electronic device according to another embodiment of the present invention.

FIG. 2B is a cross-sectional view of the handheld electronic device depicted in FIG. 2A taken along a line B-B′.

### DESCRIPTION OF EMBODIMENTS

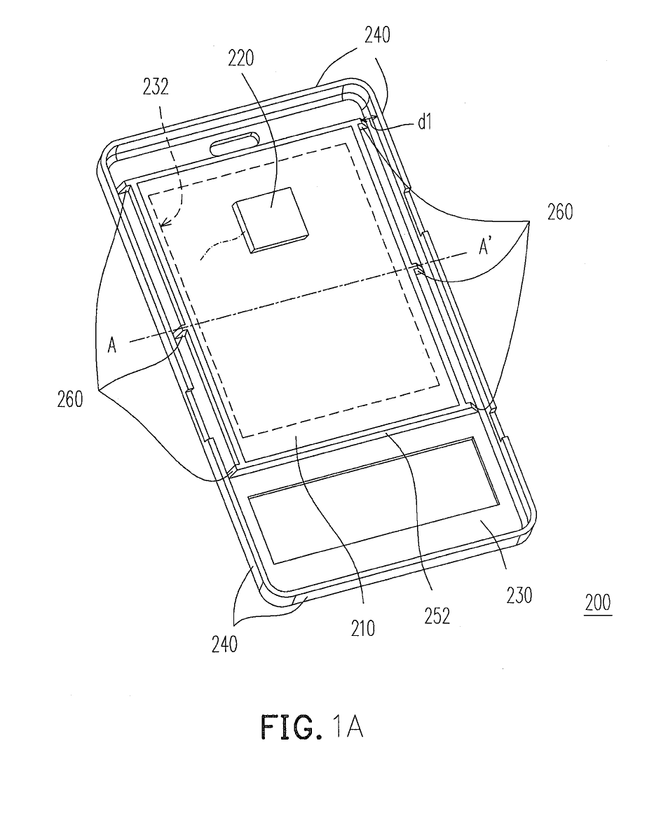

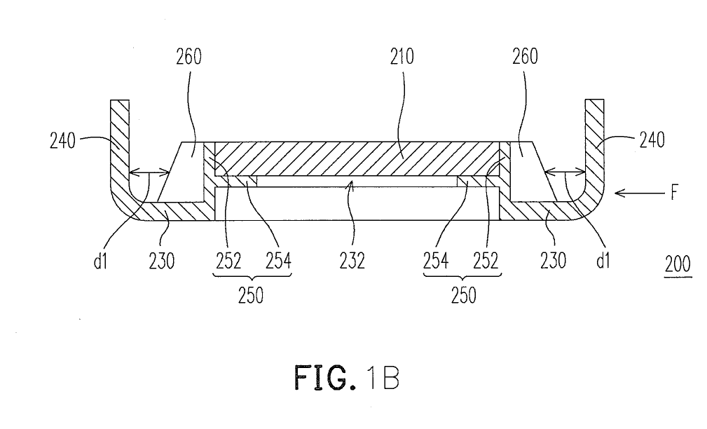

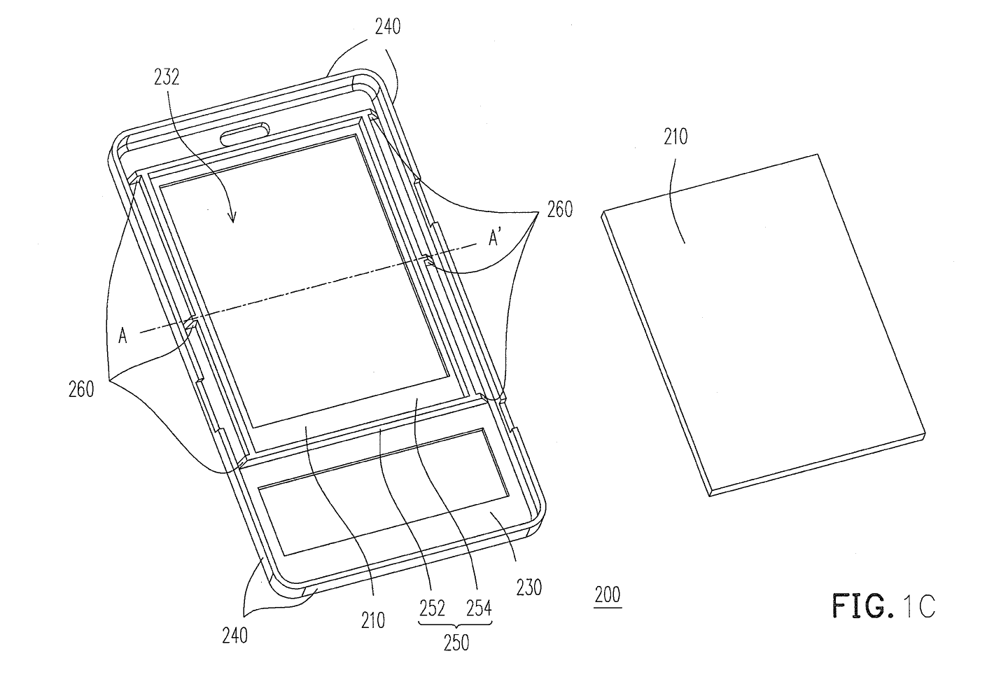

FIG. 1A is a schematic view of a handheld electronic device according to an embodiment of the present invention. FIG. 1B is a cross-sectional view of the handheld electronic device depicted in FIG. 1A taken along a line A-A′. Referring to FIGS. 1A and 1B, the handheld electronic device 200 is, for example, a cell phone or a personal digital assistant (PDA). Besides, the handheld electronic device 200 includes a display panel 210, a processing unit 220, and a fastening structure. In the present embodiment, the display panel 210 is, for example, an LCD panel or an OLED display panel. The processing unit 220 is, for example, a chip, and the processing unit 220 is connected to the display panel 210 for outputting a display signal to the display panel 210. After the display panel 210 receives the display signal, information such as pictures and texts can be displayed and shown to users.

The fastening structure includes a base plate 230, a plurality of first sidewalls 240, a frame 250, and a plurality of stiffeners 260. The first sidewalls 240 are connected together. The state of the first sidewalls 240 being connected together is not to be understood as requiring each of the first sidewalls 240 being connected to all the other ones of the first sidewalls 240. Besides, the first sidewalls 240 surround the base plate 230 and are respectively connected thereto. In the invention, the plurality of the first sidewalls 240 means at least two first sidewalls. The frame 250 is connected to the base plate 230 and surrounded by the first sidewalls 240. The stiffeners 260 are connected to the base plate 230 and the frame 250. Besides, the stiffeners 260 are located between the frame 250 and the first sidewalls 240, and a gap d1 respectively exists between each of the stiffeners 260 and each of the first sidewalls 240. In the invention, the plurality of the stiffeners 260 means at least two stiffeners.

The base plate 230, the first sidewalls 240, the frame 250, and the stiffeners 260 are integrally formed and together constitute the fastening structure for the display panel 210, for example. In addition, the handheld electronic device 200 can further include a back cover (not shown) covering the base plate 230, the first sidewalls 240, the frame 250, and the stiffeners 260. That is to say, the base plate 230, the first sidewalls 240, the frame 250, the stiffeners 260, and the back cover together form an entire case of the handheld electronic device 200.

FIG. 1C is a schematic exploded view of the handheld electronic device depicted in FIG. 1A. Referring to FIGS. 1B and 1C, in the present embodiment, the base plate 230 has a display opening 232 corresponding to the display panel 210. When the display panel 210 is disposed in the frame 250, the display opening 232 exposes a display region of the display panel 210, so as to output information and show the same to the users. Besides, a dimension of the display opening 230 approximately equates a dimension of the display region.

To be more specific, the frame 250 can have a plurality of second sidewalls 252 and a supporting portion 254. The second sidewalls 252 are connected together. The state of the second sidewalls 252 being connected together is not to be understood as requiring each of the second sidewalls 252 being connected to all the other ones of the second sidewalls 252. Besides, the second sidewalls 252 are connected to the base plate 230. When the display panel 210 is disposed in the frame 250, edges of the display panel 210 lean on the second sidewalls 252, such that a position of the display panel 210 can be fixed by the second sidewalls 252. Moreover, when the display panel 210 is disposed in the frame 250, the supporting portion 252 supports the display panel 210. Additionally, the stiffeners 260 of the present embodiment respectively have a trapezoid-shaped structure, for example, and the stiffeners 260 are connected to two of the second sidewalls 252 opposite to each other in a width direction of the handheld electronic device 200. On the other hand, some of the stiffeners 260 are connected to junctions of the second sidewalls 252, so as to strengthen the structure of the frame 250.

When an external force F is applied on one of the first sidewalls 240, the first sidewall 240 where the external force F is applied is capable of dispersing the impact caused by the external force F to the base plate 230. The stiffeners 260 are merely connected to the base plate 230 and the second sidewalls 252 but not connected to the first sidewalls 240. Therefore, when the external force F is applied on one of the first sidewalls 240, the external force F is led to the base plate 230 from the one of the first sidewalls 240. Namely, the external force F is not directly transmitted to the stiffeners 260. Thereby, not only the stiffeners 260 can strengthen the structure of the frame 250, but also the display panel 210 can be prevented from being damaged by the external force F borne by the first sidewalls 240.

Besides, the supporting portion 254 is connected to the second sidewalls 252. The position of the display panel 210 relatively parallel to the base plate 230 is fixed by the second sidewalls 252, such that the display panel 210 does not deviate from the original position due to operation by the users. The supporting portion 254 is extending from the second sidewalls 252 towards inside of the frame 250, and therefore the supporting portion 254 is able to fix the position of the display panel 210 relatively perpendicular to the base plate 230. As a result, the display panel 210 does not deviate from its original position because of operation by the users. On the other hand, a height of the first sidewalls 240 relative to the base plate 230 is substantially greater than a height of the second sidewalls 252 relative to the base plate 230.

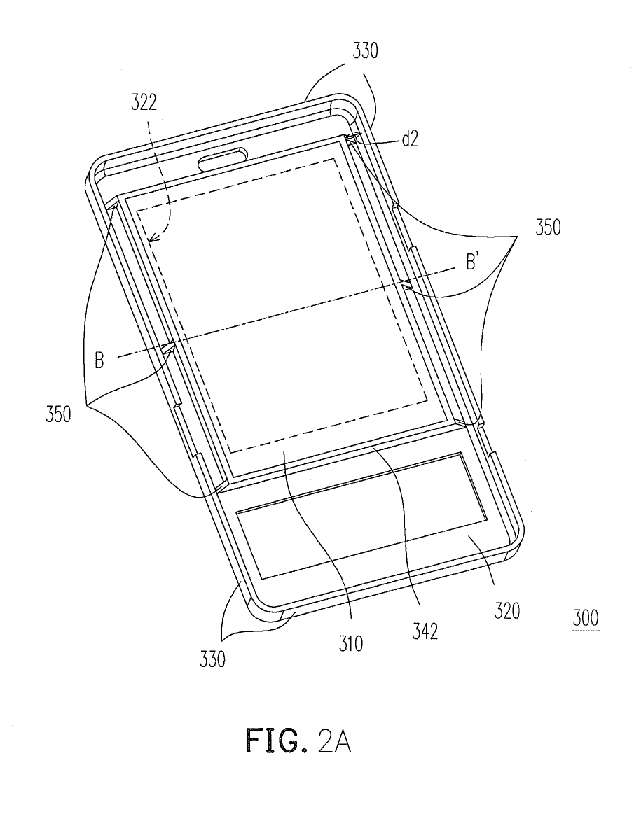

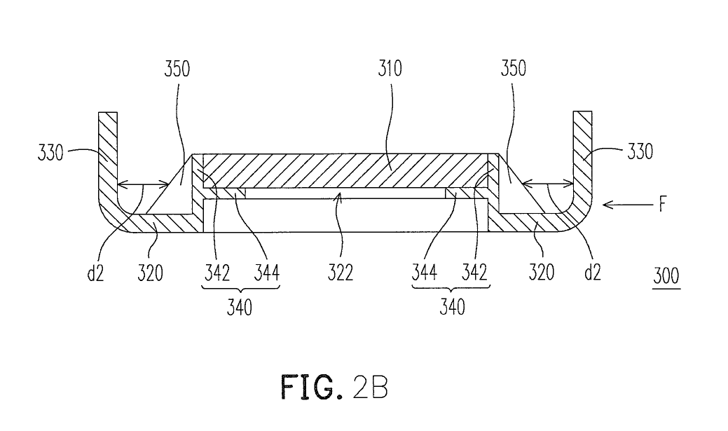

FIG. 2A is a schematic view of a handheld electronic device according to another embodiment of the present invention. FIG. 2B is a cross-sectional view of the handheld electronic device depicted in FIG. 2A taken along a line B-B′. Referring to FIGS. 2A and 2B, in the present embodiment, stiffeners 350 of the handheld electronic device 300 respectively have a triangle-shaped structure. Besides, the stiffeners 350 are located between a frame 340 and first sidewalls 330, and a gap d2 respectively exists between each of the stiffeners 350 and each of the first sidewalls 330. The stiffeners 350 are connected to second sidewalls 342 and a base plate 320. In addition, the stiffeners 350 are connected to two of the second sidewalls 342 opposite to each other in a width direction of the handheld electronic device 300. Moreover, the base plate 320, the first sidewalls 330, the frame 340, and the stiffeners 350 are integrally formed, and therefore an impact on the first sidewalls 330 can be dispersed to the base plate 320. On the other hand, some of the stiffeners 350 are connected to junctions of the second sidewalls 342, so as to strengthen the structure of the frame 340.

Referring to FIG. 2B, when an external force F is applied on the first sidewalls 330, the impact on the first sidewalls 330 where the external force F is applied is led to the base plate 320 and is not directly guided to the stiffeners 350. In other words, not only the stiffeners 350 can strengthen the structure of the frame 340, but also the display panel 310 can be better prevented from being damaged by the external force F applied to the first sidewalls 330.

To sum up, a gap respectively exists between each of the stiffeners and each of the first sidewalls according to the present invention. Thereby, the stiffeners can still strengthen the structure of the frame in the display panel. Besides, when the first sidewalls of the handheld electronic device are impacted, the external force is not transmitted to the frame through the stiffeners. As such, damages to the display panel can be prevented, and the display panel can be protected in an effective manner.

Although the invention has been described with reference to the embodiments thereof, it will be apparent to one of the ordinary skills in the art that modifications to the described embodiments may be made without departing from the spirit of the invention. Accordingly, the scope of the invention will be defined by the attached claims not by the above detailed description.

What is claimed is:

1. A fastening structure for a display panel, comprising:
a base plate;
a plurality of first sidewalls, connected together and respectively connected to the base plate;
a frame, connected to the base plate and surrounded by the plurality of first sidewalls, the frame being used for accommodating the display panel; and
a plurality of stiffeners, connected to the base plate and the frame and located between the frame and the plurality of first sidewalls, a gap respectively existing between each of the plurality of stiffeners and each of the plurality of first sidewalls.

2. The fastening structure for the display panel as claimed in claim 1, wherein the base plate has a display opening for corresponding to the display panel, and the display opening exposes a display region of the display panel when the display panel is disposed in the frame.

3. The fastening structure for the display panel as claimed in claim 1, the frame having a plurality of second sidewalls and a supporting portion, the plurality of second sidewalls being connected together and connected to the base plate, the supporting portion being connected to the plurality of second sidewalls and extending from the plurality of second sidewalls towards inside of the frame, wherein the supporting portion is used for supporting the display panel when the display panel is disposed in the frame.

4. The fastening structure for the display panel as claimed in claim 3, wherein a height of the plurality of second sidewalls relative to the base plate is substantially less than a height of the plurality of first sidewalls relative to the base plate.

5. The fastening structure for the display panel as claimed in claim 3, the plurality of stiffeners being connected to two of the plurality of second sidewalls opposite to each other.

6. The fastening structure for the display panel as claimed in claim 5, wherein at least some of the plurality of stiffeners are respectively located at junctions of the plurality of second sidewalls.

7. The fastening structure for the display panel as claimed in claim 1, the plurality of stiffeners respectively having a trapezoid-shaped structure or a triangle-shaped structure.

8. The fastening structure for the display panel as claimed in claim 1, wherein the base plate, the frame, the plurality of stiffeners, and the plurality of first sidewalls are integrally formed.

9. A handheld electronic device, comprising:
a display panel;
a processing unit, connected to the display panel for outputting a display signal to the display panel; and
a fastening structure, comprising:
a base plate;
a plurality of first sidewalls, connected together and respectively connected to the base plate;
a frame, connected to the base plate and surrounded by the plurality of first sidewalls, the frame being used for accommodating the display panel; and
a plurality of stiffeners, connected to the base plate and the frame and located between the frame and the plurality of first sidewalls, a gap respectively existing between each of the plurality of stiffeners and each of the plurality of first sidewalls.

10. The handheld electronic device as claimed in claim 9, wherein the base plate has a display opening for corresponding to the display panel, and the display opening exposes a display region of the display panel when the display panel is disposed in the frame.

11. The handheld electronic device as claimed in claim 9, the frame having a plurality of second sidewalls and a supporting portion, the plurality of second sidewalls being connected together and connected to the base plate, the supporting portion being connected to the plurality of second sidewalls and extending from the plurality of second sidewalls towards inside of the frame, wherein the supporting portion is used for supporting the display panel when the display panel is disposed in the frame.

12. The handheld electronic device as claimed in claim 11, wherein a height of the plurality of second sidewalls relative to the base plate is substantially less than a height of the plurality of first sidewalls relative to the base plate.

13. The handheld electronic device as claimed in claim 11, the plurality of stiffeners being connected to two of the plurality of second sidewalls opposite to each other.

14. The handheld electronic device as claimed in claim 11, wherein at least some of the plurality of stiffeners are respectively connected to junctions of the plurality of second sidewalls.

15. The handheld electronic device as claimed in claim 9, the plurality of stiffeners respectively having a trapezoid-shaped structure or a triangle-shaped structure.

16. The handheld electronic device as claimed in claim 9, wherein the base plate, the frame, the plurality of stiffeners, and the plurality of first sidewalls are integrally formed.

17. The handheld electronic device as claimed in claim 9, wherein the display panel is a liquid crystal display panel or an organic light emitting diode display panel.
